(19) United States
(12) Patent Application Publication
(10) Pub. No.: US 2007/0232078 A1
(43) Pub. Date: Oct. 4, 2007

(54) In situ processing for ultra-thin gate oxide scaling

(76) Inventors: Matthew V. Metz, Hillsboro, OR (US); Suman Datta, Beaverton, OR (US); Mark L. Doczy, Beaverton, OR (US); Jack T. Kavalieros, Portland, OR (US); Robert S. Chau, Beaverton, OR (US); Gilbert Dewey, Hillsboro, OR (US)

Correspondence Address: BLAKELY SOKOLOFF TAYLOR & ZAFMAN, 1279 OAKMEAD PARKWAY, SUNNYVALE, CA, 94085-4040, US

(21) Appl. No.: 11/395,853

(22) Filed: Mar. 31, 2006

(51) Int. Cl. H01L 21/31

(52) U.S. Cl. 438/778; 257/E21.621

(57) ABSTRACT

A method including depositing a material for a gate electrode on a substrate over a dielectric material, the gate electrode material comprising a metal; depositing a capping material over the gate electrode material under processing conditions that will not promote any oxygen species associated with the gate electrode material to travel through the gate electrode material to the substrate; and patterning a gate electrode structure comprising the gate electrode material.

### BACKGROUND

1. Field

Integrated circuit devices and processing.

2. Background

The scale of a transistor device requires consideration of the desired performance of the device. For example, one goal may be to increase the current flow in the semiconductor material of the transistor. The current flow is proportional to the voltage applied to the gate electrode and the capacitance seen at the gate:

Q∝C(V−Vₜₕ)

where Q is one measure of the current flow, C is capacitance, V is the voltage applied to the gate electrode, and Vₜₕ is the threshold voltage of the device.

To increase the voltage applied to a device requires an increase in power, P(P∝V²). However, at the same time as increasing the charge in the transistor, subsequent generations also seek to reduce the power required to run the device, since, importantly, a reduction of power reduces the heat generated by the device. Thus, to increase the current flow through the device without increasing the power requires an increase in the capacitance in the gate.

One way to increase the capacitance is by adjusting the thickness of the gate dielectric. In general, the capacitance is related to the gate dielectric by the following formula:

C=kₒₓ/t_{electrical}

where kₒₓ is the dielectric constant of silicon dioxide (SiO₂) and t_{electrical} is the electrical thickness of the gate dielectric.

The electrical thickness of the gate dielectric is typically greater than the actual thickness of the dielectric in most semiconductor devices. In general, as carriers flow through the channel of a semiconductor-based transistor device there is a quantum effect experienced in the channel which causes an area directly below the gate to become insulative. The insulative region acts like an extension of the gate dielectric by essentially extending the dielectric into a portion of the channel. The second cause of increase gate dielectric thickness attributable to t_{electrical} is experienced by a similar phenomenon happening in the gate electrode itself.

The result of the quantum effect in the channel and a depletion in the gate electrode is an electrical thickness (t_{electrical}) of the gate dielectric greater than the actual thickness of the gate dielectric. The magnitude of the channel quantum effect and gate electrode depletion may be estimated or determined for a given technology. Accordingly, the electrical thickness (t_{electrical}) may be calculated and scaled for a given technology.

To increase the performance of a transistor device, dielectric material having a higher dielectric constant than a dielectric constant of SiO₂ (“high k dielectric material”) have been utilized as have gate electrode of metal materials. A typical formation process is to deposit a metal film over the high k dielectric material and then cap the metal film with polysilicon or other material. The metal film is often exposed to ambient atmospheric conditions prior to capping. Under such conditions, metal films may absorb oxygen from the ambient. When a capping material requiring high temperature deposition conditions, such as a chemical vapor deposition of polycrystalline silicon (“polysilicon”) done at 600° C. or greater, is utilized, the oxygen absorbed in the metal film can travel downward into the semiconductor substrate, and oxidize the semiconductor substrate. A migration of oxygen into the semiconductor substrate tends to increase the electrical thickness (t_{electrical}) and degrade the capacitance seen at the gate.

### BRIEF DESCRIPTION OF THE DRAWINGS

Features, aspects, and advantages of embodiments will become more thoroughly apparent from the following detailed description, appended claims, and accompanying drawings in which:

FIG. 1 shows a portion of a semiconductor substrate having an oxide layer formed on a surface thereof and a high k dielectric material formed on the oxide layer.

FIG. 2 shows the structure of FIG. 1 following the deposition of a metal film on the high k dielectric.

FIG. 3 shows the structure of FIG. 2 following the deposition of a capping layer on the metal film.

FIG. 4 shows the structure of FIG. 3 following the patterning of a gate electrode over a gate dielectric.

### DETAILED DESCRIPTION

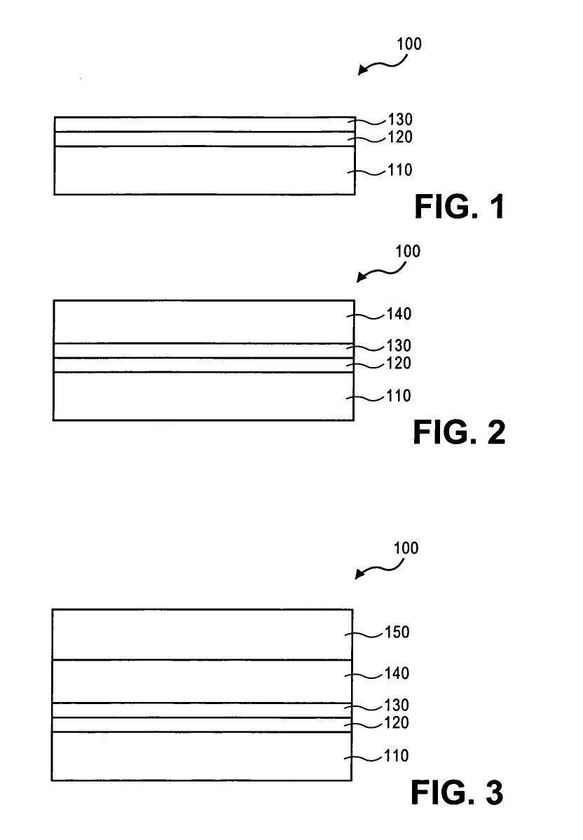

FIG. 1 shows a portion of a substrate, such as a wafer (e.g., silicon wafer) designated for circuit devices to form, for example, a microprocessor chip. Structure 100 includes substrate 110, such as a silicon substrate or a silicon on insulator (SOI) substrate. In one embodiment, circuit devices, such as transistor devices, will be formed in and on a surface of substrate 110. Typically, for a substrate of a silicon wafer, the surface of the wafer is oxidized (e.g., thermal oxidation) to a thickness on the order of 200 angstroms (Å). The oxidized surface is then removed (e.g., etched away) to bare silicon. The surface is then cleaned and oxidized again (e.g., thermal oxidation). FIG. 1 shows substrate 110 having silicon dioxide (SiO₂) film 120 formed thereon. The oxidation may be formed via a wet chemical clean or grown in a furnace. In one embodiment, a suitable thickness for SiO₂ film 120 is on the order of three to 20 angstroms (Å). Representatively, in one embodiment, film 120 formed by a wet chemical clean may be on the order of 3 Å to 10 Å.

Following the oxidation of a surface of substrate 110 (the superior surface as viewed), substrate 110 is transferred to a deposition tool for depositing a dielectric material having a dielectric constant greater than a dielectric constant of SiO₂ (a “high k” dielectric material). Suitable deposition tools include tools capable of depositing a high k dielectric material using atomic layer deposition (ALD) or chemical vapor deposition (CVD) techniques. Suitable high k dielectric materials include, but are not limited to, hafnium oxide (HfO₂), zirconium oxide (ZrO₂), lanthanum oxide (La₂O₃) and yittrium oxide (Y₂O₃). FIG. 1 shows high k dielectric material layer 130 deposited as a blanket on SiO₂ layer 120. A representative thickness of high k dielectric material layer 130 of HfO₂ is on the order of 20 Å.

Following the deposition of high k dielectric material layer 130, structure 100 is transferred to a metal deposition tool. Typical transfer of structure 100 from a high k dielectric material layer deposition tool to a metal deposition tool exposes structure 100 to ambient conditions.

FIG. 2 shows structure 100 following the deposition of metal containing film 140. A metal containing film, including, but not limited to, titanium nitride (TiN) or tantalum nitride (TaN) may be deposited using physical vapor deposition techniques in a sputter tool. In one embodiment, a deposition process is done under vacuum conditions on the order of 10⁻⁸ torr.

FIG. 2 shows structure 100 including metal containing film 140 on high k dielectric material layer 130. In one embodiment, metal containing film 140 has a thickness on the order of 5 Å to 25 Å. In another embodiment, the thickness of metal containing film 140 is on the order of 10 Å to 25 Å.

FIG. 3 shows the structure of FIG. 2 following the deposition of capping layer 150 on metal containing film 140. In one embodiment, capping layer 150 is deposited by sputtering, such as PVD. In an example where capping layer 130 is a silicon material, silicon may be sputter deposited by PVD with substrate 110 at a temperature of −100° C. to 225° C., representatively 100° C. The sputter deposition of silicon will result in capping layer 150 of amorphous silicon.

By depositing capping layer 150 using a sputter (e.g., PVD) deposition technique, the deposition temperature may be kept at in minimum. This is in contrast to, for example, chemical vapor deposition of, for example, silicon, which requires temperatures of 600° C. or greater. By depositing capping layer 150 at a reduced temperature, the migration of any absorbed oxygen in metal containing film 130 may be minimized.

In another embodiment, the ability of metal containing layer 140 to absorb oxygen from the ambient is minimized by depositing metal containing film 140 and capping layer 150 in situ. By “in situ” is meant that metal containing film 140 and capping layer 150 may be deposited without exposing structure 100 to ambient conditions between depositions. This may be accomplished, for example, by maintaining the pressure conditions (e.g., vacuum conditions) for both depositions and/or by using one tool for the deposition of metal containing film 140 and capping layer 150. In the case of sputter deposition of each of metal containing film 140 and capping layer 150, a suitable tool may be a multi-chamber tool.

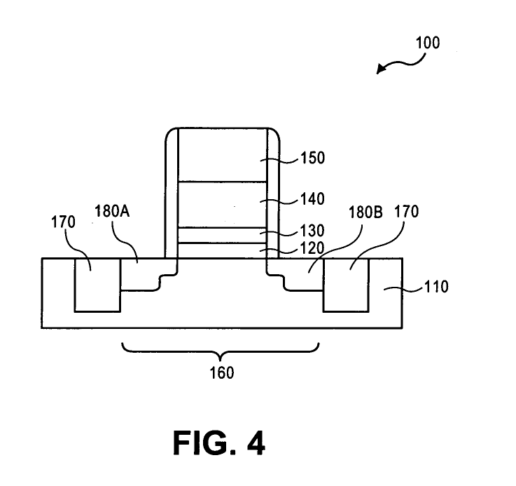

FIG. 4 shows the structure of FIG. 3 following the patterning of the material layers on a surface of substrate 110 into a gate electrode on a gate dielectric on the substrate. FIG. 4 shows a composite gate dielectric of SiO₂ layer 120 and high k dielectric material layer 130. FIG. 4 shows composite gate electrode of metal containing film 140 and capping layer 150 of, for example, silicon. In one example, capping layer 150 of silicon to be utilized as a portion of gate electrode may have a thickness on the order of 25 Å to 120 Å, the thicker the capping layer the tendency to increase the capacitance at the gate or reduce t_{electrical}.

One way to pattern the composite gate electrode and composite gate dielectric as shown in FIG. 4 is through photolithographic techniques wherein, for example, a photoresist material is patterned to expose an area over an area designated for the gate electrode. The blanket-deposited capping layer 150, metal containing film 140, high k dielectric material layer 130 are then etched as is SiO₂ layer 120. FIG. 4 shows the composite gate electrode and composite gate dielectric in active area 160 of substrate 100 following patterning. Active area 160 is defined, in one embodiment, by shallow trench isolation structure 170. FIG. 4 also shows source region 180A and drain region 180B formed in substrate 110 as part of the transistor device.

In the embodiment shown in FIG. 4, capping layer 150 of, for example, silicon, is retained as part of a composite gate electrode. In another embodiment, capping layer may be removed in subsequent processing operations and optionally replaced. Accordingly, a material for capping layer 150 is selected, in one embodiment, to act as a seal material to, for example, hermetically seal metal containing film 140 to minimize the absorption of oxygen by metal containing film during subsequent processing operations. Thus, materials other than silicon are as a material for capping layer 150. A suitable material for a sacrificial layer is, for example, silicon nitride.

In an embodiment where containing film 140 may be exposed to ambient conditions prior to the deposition of capping layer 150, a material for capping material 150 should be selected such that it may be deposited under conditions (e.g., a temperature) that will not encourage the migration of any oxygen containing species in metal containing film 140 to migrate toward substrate 110.

In the preceding detailed description, reference is made to specific embodiments thereof. It will, however, be evident that various modifications and changes may be made thereto without departing from the broader spirit and scope of the following claims. The specification and drawings are, accordingly, to be regarded in an illustrative rather than a restrictive sense.

What is claimed is:

1. A method comprising:
depositing a material for a gate electrode on a substrate over a dielectric material, the gate electrode material comprising a metal;
depositing a capping material over the gate electrode material under processing conditions that will not promote any oxygen species associated with the gate electrode material to travel through the gate electrode material to the substrate; and
patterning a gate electrode structure comprising the gate electrode material.

2. The method of claim 1, wherein the capping material comprises silicon and depositing the capping material comprises physical vapor deposition.

3. The method of claim 1, wherein depositing the capping material comprises depositing under conditions where the wafer is at temperature of −100° C. to 225° C.

4. The method of claim 1, wherein depositing the gate electrode material and depositing the capping material are done in situ.

5. The method of claim 1, wherein the dielectric material comprises a dielectric constant greater than a dielectric constant of silicon dioxide.

6. The method of claim 1, wherein the patterned gate electrode structure comprises the capping material.

7. A method comprising:
depositing a material for a gate electrode on a substrate over a dielectric material, wherein the dielectric material has a dielectric constant greater than a dielectric constant of silicon dioxide;
depositing a capping material over the gate electrode material; and
patterning a gate electrode structure comprising the gate electrode material over a gate dielectric comprising the dielectric material,
wherein the capping material is deposited under processing conditions that do not increase an electrical thickness of the gate dielectric.

8. The method of claim 7, wherein the capping material comprises silicon and depositing the capping material comprises physical vapor deposition.

9. The method of claim 7, wherein depositing the capping material comprises depositing under conditions where the wafer is at temperature of −100° C. to 225° C.

10. The method of claim 7, wherein depositing the gate electrode material and depositing the capping material are done in situ.

11. The method of claim 7, wherein the material for the gate electrode comprises a metal.

12. The method of claim 1, wherein the patterned gate electrode structure comprises the capping material.

13. A method comprising:
depositing a material for a gate electrode on a substrate over a dielectric material, the gate electrode material comprising a metal;
depositing a capping material over the gate electrode material; and
patterning a gate electrode structure comprising the gate electrode material,
wherein depositing the material for the gate electrode and the capping material are done in situ.

14. The method of claim 13, wherein the dielectric material has a dielectric constant greater than a dielectric constant of silicon dioxide.

15. The method of claim 13, wherein the capping material comprises silicon and depositing the capping material comprises physical vapor deposition.

16. The method of claim 15, wherein depositing the capping material comprises depositing under conditions where the wafer is at temperature of −100° C. to 225° C.
